(19) United States
(12) Patent Application Publication
(10) Pub. No.: US 2005/0200235 A1
(43) Pub. Date: Sep. 15, 2005

(54) Potassium niobate deposited body, method for manufacturing the same, surface acoustic wave element, frequency filter, frequency oscillator, electronic circuit, and electronic apparatus

(76) Inventors: Takamitsu Higuchi, Nagano (JP); Setsuya Iwashita, Nagano (JP); Hiromu Miyazawa, Nagano (JP)

Correspondence Address: HARNESS, DICKEY & PIERCE, P.L.C., P.O. BOX 828, BLOOMFIELD HILLS, MI, 48303, US

(21) Appl. No.: 11/075,153

(22) Filed: Mar. 8, 2005

(30) Foreign Application Priority Data
Mar. 12, 2004 (JP) 2004-070989

(51) Int. Cl. H03H 9/25

(52) U.S. Cl. 310/313 R

(57) ABSTRACT

A potassium niobate deposited body includes a sapphire substrate, and a potassium niobate layer formed above the sapphire substrate. The potassium niobate deposited body further includes a buffer layer consisting of a metal oxide formed above the sapphire substrate, wherein the potassium niobate layer is formed above the buffer layer.

### RELATED APPLICATIONS

This application claims priority to Japanese Patent Application No. 2004-070989 filed Mar. 12, 2004 which is hereby expressly incorporated by reference herein in its entirety.

### BACKGROUND

1. Technical Field

The present invention relates to potassium niobate deposited bodies, methods for manufacturing the same, surface acoustic wave elements, frequency filters, frequency oscillators, electronic circuits, and electronic apparatuses, which are used in, for example, telecommunications equipment.

2. Related Art

Accompanying the remarkable progress of the telecommunications field focusing primarily on cellular telephones and other mobile communications, the demand for surface acoustic wave elements is increasing rapidly. The development of surface acoustic wave elements is directed toward achieving further miniaturization, higher efficiency, and higher frequency. In order to accomplish this, a larger electromechanical coupling coefficient (k²), a more stable temperature characteristic, and a greater surface acoustic wave propagation velocity are needed. For example, when a surface acoustic wave element is used as a high frequency filter, a higher electromechanical coupling coefficient is desired to obtain a passband region with a low loss and a wide bandwidth. To make the resonance frequency to be a higher frequency, materials with a greater acoustic velocity are desired even in view of the limit in the design rule of the pitch of inter-digital type electrodes (inter-digital transducers). In addition, a central frequency temperature coefficient (TCF) needs to be small to stabilize the characteristics in the use temperature range.

Conventionally, a structure in which an inter-digital transducer is formed on a piezoelectric single crystal has been primarily used in surface acoustic wave elements. Typical examples of piezoelectric single crystals include quartz crystal, lithium niobate (LiNbO₃) and lithium tantalate (LiTaO₃). For example, in the case of RF filters that require a broader band and reduced loss of the pass band, LiNbO₃ having a large electromechanical coupling coefficient is used. On the other hand, in the case of IF filters requiring stable temperature characteristics even in a narrow band, quartz crystal having a small electromechanical coupling coefficient is used. Moreover, LiTaO₃, in which the electromechanical coupling coefficient and the central frequency temperature coefficient are between those of LiNbO₃ and quartz crystal, plays an intermediate role between the two. However, even in LiNbO₃ with a largest electromechanical coupling coefficient, its electromechanical coupling coefficient was about 20%.

Recently, in potassium niobate (KNbO₃) (a=0.5695 nm, b=0.5721 nm, and c=0.3973 nm; hereafter this index expression is followed as orthorhombic crystal) single crystal, a cut angle that exhibits a large value of electromechanical coupling coefficient was found. As described in Electron. Lett. Vol. 33 (1997) 193, it was predicted by calculation that a 0° Y-cut X propagation (hereafter referred to as “0° Y-X”) KNbO₃ single crystal plate would have a very large value of electromechanical coupling coefficient reaching as much as 53%. Furthermore, as described in Jpn. J. Appl. Phys. Vol. 37 (1998) 2929, it was confirmed even by experiments that a Y-XKNbO₃ single crystal plate exhibited a large value of electromechanical coupling coefficient of 50%, and it was reported that the oscillation frequency of a filter using 45° to 75° rotated Y—XKNbO₃ single crystal substrates exhibited a zero-temperature characteristic around room temperature. Rotated Y-XKNbO₃ single crystal plates including these 0° Y-X KNbO₃ are described in Japanese Laid-open Patent Application HEI 10-65488.

In a surface acoustic wave element that uses a piezoelectric single crystal substrate, its characteristics such as the electromechanical coupling coefficient, temperature coefficient, and acoustic velocity define values peculiar to the material used, and are decided according to a cut angle and a propagation direction. A 0° Y-XKNbO₃ single crystal substrate is excellent in the electromechanical coupling coefficient, but does not exhibit a zero-temperature characteristic like 45° to 75° rotated Y-XKNbO₃ single crystal substrates around room temperature. Moreover, its propagation velocity is slower compared to SrTiO₃ and CaTiO₃ which are the same perovskite type oxide. Thus, all of the requirements of high acoustic velocity, high electromechanical coupling coefficient, and zero-temperature characteristic cannot be satisfied by merely using a KNbO₃ single crystal substrate.

Then, the improvement of acoustic velocity, electromechanical coupling coefficient, and temperature characteristic may be expected through depositing a piezoelectric thin film on a certain substrate, and controlling the film thickness. A structure in which a zinc oxide (ZnO) thin film is formed on a sapphire substrate described in Jpn. J. Appl. Phys. Vol. 32 (1993) 2337, and a structure in which a LiNbO₃ thin film is formed on a sapphire substrate described in Jpn. J. Appl. Phys. Vol. 32 (1993) L745 can be enumerated. Therefore, the improvement of all of the characteristics can be expected through forming a thin film of KNbO₃ on a substrate.

It is noted here that a piezoelectric thin film may preferably be oriented to a direction optimum to extract the electromechanical coupling coefficient and the temperature characteristic, and may preferably be a flat and dense epitaxial film to reduce the loss caused by leaky wave propagation as much as possible. Y-XKNbO₃ whose electromechanical coupling coefficient is 50% corresponds to pseudo cubic crystal (100). 90° Y-XKNbO₃ whose electromechanical coupling coefficient is 10% corresponds to pseudo cubic crystal (110). Therefore, for example, by using a SrTiO₃ (100) or (110) single crystal substrate, it can be expected to obtain a Y-XKNbO₃ film whose electromechanical coupling coefficient is 50% or a 90° Y-XKNbO₃ film whose electromechanical coupling coefficient is 10%.

However, at present, a potassium niobate single phase thin film, and, a Y-X epitaxial potassium niobate thin film cannot be formed on an insulation substrate of a large surface area.

It is an object of the present invention to provide potassium niobate deposited body wherein a polycrystal or single crystal potassium niobate thin layer is formed on an insulating substrate, and a method for manufacturing the same.

It is another object of the present invention to provide a surface acoustic wave element that can be accommodated for higher frequency applications and has a high electromechanical coupling coefficient, with which the effect of miniaturization and power saving can be expected.

It is still another object of the present invention to provide a frequency filter, a frequency oscillator, an electronic circuit, and an electronic apparatus, which include the surface acoustic wave element described above.

### SUMMARY

A potassium niobate deposited body in accordance with the present invention includes:
a sapphire substrate; and
a potassium niobate layer formed above the sapphire substrate.

In accordance with the present invention, a potassium niobate deposited body in which a potassium niobate thin film having a high electromechanical coupling coefficient is formed on an insulation substrate can be provided.

The potassium niobate deposited body in accordance with the present invention may further include a buffer layer consisting of a metal oxide formed above the sapphire substrate, wherein the potassium niobate layer may be formed above the buffer layer. According to the present invention, because the buffer layer is provided on the sapphire substrate, a potassium niobate layer having an excellent crystallinity can be obtained.

It is noted that, in the present invention, forming “B” above “A” includes a case in which “B” is formed directly on “A” and a case in which “B” is formed over “A” through a member different from “A” or “B.”

In the potassium niobate deposited body in accordance with the present invention, the potassium niobate layer may include a domain having a polarization axis that is in parallel with the sapphire substrate. Also, in accordance with the present invention, the potassium niobate layer can include a domain that epitaxially grows in a (001) orientation, when a lattice constant of orthorhombic potassium niobate is 2^{1/2}c<a<b, and a b-axis is a polarization axis. According to the present invention, because the potassium niobate layer has the above-described domain, it has a high electromechanical coupling coefficient.

In the potassium niobate deposited body in accordance with the present invention, the sapphire substrate can be an R-plane (1-102). By using such a sapphire substrate, a buffer layer that epitaxially grows can be obtained.

In the potassium niobate deposited body in accordance with the present invention, the buffer layer may consist of a metal oxide having a rock salt structure. Such a metal oxide can be magnesium oxide. Further, the magnesium oxide may be epitaxially grown in a cubic (100) orientation. By using such a buffer layer, a polycrystal or single crystal potassium niobate layer can be formed.

In the potassium niobate deposited body in accordance with the present invention, a [100] direction vector of the magnesium oxide and a [001] direction vector of the epitaxially grown domain of the potassium niobate layer are inclined with respect to a normal vector of the R-plane (1-102) of the sapphire substrate. It is noted here that the tilt angle with respect to the normal vector can be 1 degree or greater but 20 degrees or less.

In the potassium niobate deposited body in accordance with the present invention, the above-described potassium niobate layer can be replaced with a layer of potassium niobate solid solution. The layer of potassium niobate solid solution can consist of a solid solution shown by K₁₋ₓNaₓNb_{1-y} Ta_{y}O₃ (0<x<1, 0<y<1).

A method for manufacturing a potassium niobate deposited body in accordance with the present invention may include:
a step of forming a buffer layer consisting of a metal oxide having a rock salt structure above a sapphire substrate; and
a step of forming a potassium niobate polycrystal or single crystal layer above the buffer layer.

The manufacturing method in accordance with the present invention can further include the step of polishing a surface of the potassium niobate layer.

A surface acoustic wave element in accordance with the present invention includes a potassium niobate deposited body in accordance with the present invention and an electrode.

In the surface acoustic wave element in accordance with the present invention, a surface of the potassium niobate layer or the potassium niobate solid solution layer of the potassium niobate deposited body may be polished.

A frequency filter in accordance with the present invention includes the surface acoustic wave element in accordance with the present invention.

A frequency oscillator in accordance with the present invention includes the surface acoustic wave element in accordance with the present invention.

An electronic circuit in accordance with the present invention includes the frequency oscillator in accordance with the present invention.

An electronic apparatus in accordance with the present invention includes at least one of the frequency filter, the frequency oscillator and the electronic circuit in accordance with the present invention.

### BRIEF DESCRIPTION OF THE DRAWINGS

FIGS. 1(A)-(C) are cross-sectional views showing a potassium niobate deposited body in accordance with an embodiment of the present invention and its manufacturing method.

FIGS. 2(A) and (B) are scanning electron microscope (SEM) microphotographs of surfaces of potassium niobate layers obtained in accordance with an embodiment of the present invention.

FIG. 3 is an X-ray diffraction diagram of potassium niobate obtained in accordance with an embodiment of the present invention.

FIGS. 4(A)-(C) are RHEED patterns of potassium niobate obtained in accordance with an embodiment of the present invention.

FIG. 5 is an X-ray diffraction diagram of potassium niobate obtained in accordance with an embodiment of the present invention.

FIG. 6 is an X-ray diffraction diagram pole figure of potassium niobate obtained in accordance with an embodiment of the present invention.

FIG. 7 is a cross-sectional view of a surface acoustic wave element in accordance with an embodiment of the present invention.

FIG. 8 is a perspective view of the external appearance of a frequency filter in accordance with an embodiment of the present invention.

FIG. 9 is a perspective view of the outer appearance of a frequency oscillator in accordance with an embodiment of the present invention.

FIGS. 10(A) and (B) are a cut-out side view and a cut-out plan view respectively of an example in which a surface acoustic wave element (frequency oscillator) in accordance with an embodiment of the present invention is applied to a VCSO.

FIG. 11 is a block diagram of the basic structure of a PLL circuit.

FIG. 12 is a block diagram showing the electric composition of an electronic circuit in accordance with an embodiment of the present invention.

FIG. 13 is a perspective view of the external appearance of a cellular phone as one example of an electronic apparatus in accordance with an embodiment of the present invention.

FIG. 14 is a view showing a communications system that uses a reader/writer in accordance with an embodiment of the present invention.

FIG. 15 is a block diagram schematically showing the reader/writer shown in FIG. 14.

FIG. 16 is a circuit diagram showing the structure of the reader/writer shown in FIG. 15.

### DETAILED DESCRIPTION

Embodiments of the present invention are described below with reference to the drawings.

### 1. Potassium Niobate Deposited Body and Its Manufacturing Method

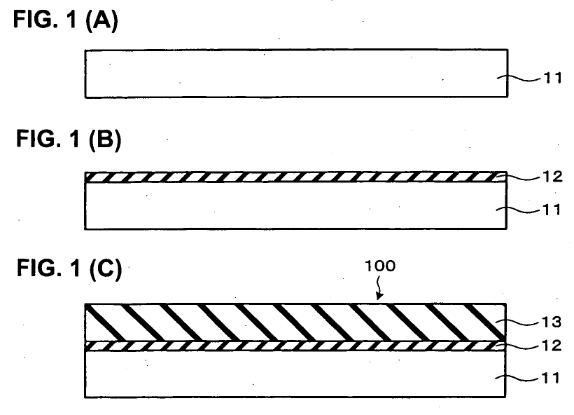

FIGS. 1(A)-(C) are cross-sectional views schematically indicating a potassium niobate deposited body in accordance with an embodiment of the present invention, and a method for manufacturing the same.

### 1.1 Potassium Niobate Deposited Body

As shown in FIG. 1(C), a potassium niobate deposited body 100 in accordance with the present embodiment includes a sapphire single crystal substrate 11, a buffer layer 12 that consists of magnesium oxide (MgO) formed on the sapphire single crystal substrate 11, and a potassium niobate layer 13 formed on the buffer layer 12.

An R-plane (1-102) substrate can be used as the sapphire single crystal substrate 11. Such a sapphire single crystal substrate is desirable because it is a large surface area substrate in which the buffer layer 12 and the potassium niobate layer 13 can be epitaxially grown, and can be obtained at a low price.

The buffer layer 12 consists of magnesium oxide (MgO), and has a cubic (100) orientation. The thickness of the buffer layer 12 is not particularly limited, but may be 5 nm or greater but 100 nm or less, in view of preventing the sapphire single crystal substrate 11 and the potassium niobate layer 13 from reacting each other, and preventing the potassium niobate layer 13 from being deteriorated because of the deliquescence of magnesium oxide itself By using MgO with a cubic (100) orientation as the buffer layer 12, a potassium niobate layer that has a specific domain to be described below can be obtained.

Here, the benefit in using MgO with a cubic (100) orientation as the buffer layer 12 is not only that MgO can epitaxial grow a potassium niobate layer 13 on the sapphire single crystal substrate 11, but also that the dielectric property of the potassium niobate layer 13 is not deteriorated even when Mg²⁺ substitutes Nb⁵⁺ in the potassium niobate layer 13 and K (Mg, Nb) O₃ is generated.

The potassium niobate layer 13 has a polycrystal or single crystal structure. The thickness of the potassium niobate layer 13 is not particularly limited, and appropriately selected depending on devices to be applied, but for example, it can be 100 nm or greater but 10000 nm or smaller.

The potassium niobate layer 13 can further have the following characteristics.

That is, the potassium niobate layer 13 can include a domain whose polarization axis is in parallel with the sapphire single crystal substrate 11.

More specifically, the potassium niobate layer 13 may preferably include a domain that epitaxially grows in a (001) orientation, when the lattice constant of orthorhombic potassium niobate is 2^{1/2} c<a<b and a b-axis is a polarization axis. The potassium niobate layer 13 including such a domain can have a high electromechanical coupling coefficient.

In addition, as described below in detail, when the potassium niobate layer 13 consists of a single crystal, a [100] direction vector of the magnesium oxide composing the buffer layer 12 and a [001] direction vector of the epitaxially grown domain of the potassium niobate layer may preferably be inclined with respect to a normal vector of the R-plane (1-102) of the sapphire substrate. The inclination angle with respect to the normal vector may preferably be 1 degree or greater but 20 degrees or less.

In the present embodiment, instead of the potassium niobate layer described above, it may be a layer of potassium niobate solid solution in which a part of niobium and potassium of potassium niobate is replaced with other elements. As the potassium niobate solid solution, for example, a solid solution shown by K₁₋ₓ NaₓNb_{1-y} Ta_{y}O₃ (0<x<1, 0<y<1) can be enumerated.

### 1.2 Method for Manufacturing Potassium Niobate Deposited Body

Next, a method for manufacturing a potassium niobate deposited body is described.

(1) As shown in FIG. 1(A), a sapphire single crystal substrate 11 is prepared. The sapphire single crystal substrate 11 has been degreased and washed beforehand. Degreasing and washing can be conducted by soaking the sapphire single crystal substrate in an organic solvent and using an ultrasonic washing machine. The organic solvent is not particularly limited, but may be a mixed solution of ethyl alcohol and acetone.

(2) A buffer layer 12 that consists of MgO is formed on the sapphire single crystal substrate 11 by a laser ablation method, as shown in FIG. 1(B).

More specifically, after the sapphire single crystal substrate 11 that has been degreased and washed is loaded onto a substrate holder, it is introduced together with the substrate holder in a vacuum apparatus whose back pressure at room temperature is 1×10⁻⁸ Torr. Next, oxygen gas is introduced such the oxygen partial pressure becomes 5×10⁻⁵ Torr, for example, and then the substrate is heated to elevate its temperature up to 400° C. at a rate of 20° C./minute with an infrared ray lamp. It is noted that the conditions such as the rate of temperature elevation, substrate temperature, pressure, etc. are not limited to the above.

Next, a plume is generated by a laser ablation method in which a laser beam is irradiated to a magnesium target for a buffer layer, thereby pounding out magnesium atoms from the target. Then, this plume is irradiated toward the sapphire single crystal substrate 11, and contacts the sapphire single crystal substrate 11, whereby MgO with a cubic (100) orientation is formed by epitaxial growth on the sapphire single crystal substrate 11.

As the method to pound out magnesium atoms or desired atoms from a target in a later step, besides the method of irradiating a laser beam to a target surface described above, for example, a method of irradiating (injecting) argon gas (inert gas) plasma or an electron beam to a target surface can also be used. However, the method of irradiating a laser beam to a target surface is desirable among them. According to such a method, atoms can be readily and securely pounded out from a target, with a vacuum apparatus of a simple composition equipped with an incident window of a laser beam

The laser beam to be irradiated to a target may preferably be a pulsed beam with a wavelength of about 150-300 nm, and a pulse length of about 1-100 ns. More specifically, the laser beam may be, for example, an excimer laser such as an ArF excimer laser, a KrF excimer laser, a XeCl excimer laser, or the like, a YAG laser, a YVO₄ laser, a CO₂ laser or the like. Among the above, the ArF excimer laser and the KrF excimer laser are particularly preferred. The ArF excimer laser and the KrF excimer laser are easy to handle, and can effectively pound atoms from the first target.

Each of the conditions at the time of laser beam irradiation is not particularly limited as long as the magnesium plasma can sufficiently reach the substrate, and MgO as the buffer layer can be epitaxially grown.

For example, the conditions at the time of laser beam irradiation are as follows. The energy density of the laser beam may preferably be between 2 J/cm² and 4 J/cm². The frequency of the laser beam may preferably be between 5 Hz and 20 Hz. The distance between the target and the substrate may preferably be between 30 mm and 100 mm. The temperature of the substrate may preferably be between 300° C. and 600° C. The partial pressure of oxygen during deposition may preferably be between 1×10⁻⁵ Torr and 1×10⁻³ Torr.

(3) As shown in FIG. 1(C), a potassium niobate layer 13 is formed by a laser ablation method on the buffer layer 12.

More specifically, a plume is generated by a laser ablation method in which a laser beam is irradiated to a target for a potassium niobate layer, for example, a K_{0.6}Nb_{0.4}O_{y} target, thereby pounding out potassium, niobium and oxygen atoms from this target. Then, the plume is irradiated toward the sapphire single crystal substrate 11, and contacts the buffer layer 12, whereby a potassium niobate layer 13 is formed on the buffer layer 12.

In the laser ablation method, the conditions at the time of laser beam irradiation may not be particularly limited as long as the potassium and niobium plasma can sufficiently reach the substrate. For example, the conditions may be as follows. The energy density of the laser beam may preferably be between 2 J/cm² and 4 J/cm². The frequency of the laser beam may preferably be between 5 Hz and 20 Hz. The distance between the target and the substrate may preferably be between 30 mm and 100 mm. The temperature of the substrate may preferably be between 600° C. and 800° C. The partial pressure of oxygen during deposition may preferably be between 1×10⁻² Torr and 1 Torr.

In this step, by selecting each of the conditions at the time of laser ablation, potassium niobate becomes to have a polycrystal (preferably polycrystal of a single phase) or single crystal structure.

Through the steps described above, a potassium niobate deposited body 100 in which the buffer layer 12 and the potassium niobate layer 13 consisting of MgO are sequentially deposited on the sapphire single crystal substrate 11 is obtained.

In addition, a polishing process to planarize the surface of the potassium niobate layer 13 can be conducted if necessary. Buff polishing, CMP (Chemical Mechanical Polishing) or the like can be used as such a polishing process.

In the above-described process, a K_{0.6}Nb_{0.4}O_{y} target is used in the step (3) for forming the potassium niobate layer 13. However, the composition ratio of the target is not limited to the above. For example, for the formation of the potassium niobate layer, it is possible to use a target having a composition ratio that is suitable for conducting a Tri-Phase-Epitaxy method, in which a vapor phase raw material is deposited on a substrate that is maintained at temperatures in a solid-liquid coexisting region, and a solid phase is precipitated from a liquid phase. Concretely, when the temperature and the mole composition ratio at an eutectic point E of KNbO₃ and 3K₂O.Nb₂O₅ under a prescribed oxygen partial pressure are assumed to be T_{E} and x_{E}, respectively, (x is a mole composition ratio of potassium (K) and niobium (Nb) when they are expressed by KₓNb₁₋ₓO_{y}), a plasma plume that is a raw material in the state of a vapor phase is supplied to a base substrate (which, in this example, consists of a sapphire substrate and a buffer layer formed on the substrate), such that the composition x in the state of a liquid phase immediately after being deposited on the base substrate is in the range of 0.5≦x≦x_{E}. When a complete melting temperature at this oxygen partial pressure and the composition x is assumed to be Tₘ, and the temperature Tₛ of the base substrate is maintained within the range of T_{E}≦T₅≦Tₘ, KNbO₃ single crystal can be precipitated from KₓNb₁₋ₓO_{y} on the base substrate, while evaporating the remaining liquid of KₓNb₁₋ₓO_{y} deposited on the base substrate from the plasma plume 24.

It is noted that, in the present embodiment, a laser ablation method is used as a film forming method for forming the buffer layer and the potassium niobate layer. However, the film forming method is not limited to this, and, for example, a vapor deposition method, a MOCVD method, and a sputter method can be used.

### 1.3 Embodiment Examples

### (1) First Embodiment Example

A potassium niobate deposited body was formed by the following method. In this embodiment example, a polycrystal potassium niobate layer of a single phase could be obtained.

First, a sapphire single crystal substrate was degreased and washed by soaking the sapphire single crystal substrate in an organic solvent with an ultrasonic washing machine. As the organic solvent, a 1:1 mixed solution of ethyl alcohol and acetone was used. After loading the sapphire single crystal substrate that had been degreased and washed onto a substrate holder, it was introduced together with the substrate holder in a vacuum apparatus whose back pressure at room temperature was 1×10⁻⁸ Torr, oxygen gas was introduced such the oxygen partial pressure became 5×10⁻⁵ Torr, and then the substrate was heated to elevate its temperature up to 400° C. at a rate of 20° C./minute with an infrared ray lamp.

Next, a pulsed beam of KrF excimer laser (with a wavelength of 248 nm) was injected in a surface of a magnesium target under conditions with an energy density being 3 J/cm², a frequency being 10 Hz, and a pulse length being 10 ns, thereby generating a plasma plume of magnesium on the target surface. The plasma plume was irradiated to the sapphire single crystal substrate at a position 70 mm away from the target for 30 minutes under conditions with a substrate temperature being 400° C. and an oxygen partial pressure being 5×10⁻⁵ Torr, whereby an epitaxially grown buffer layer consisting of MgO was deposited to a thickness of 10 nm.

Next, a pulsed beam of KrF excimer laser was injected in a surface of a K_{0.6}Nb_{0.4}O_{y} target under conditions with an energy density being 3 J/cm², a frequency being 10 Hz, and a pulse length being 10 ns, thereby generating a plasma plume of K, Nb and O. The plasma plume was irradiated to the sapphire single crystal substrate at a position 70 mm away from the target for 240 minutes under conditions with a substrate temperature being 750° C. and an oxygen partial pressure being 1×10⁻¹ Torr, whereby a potassium niobate layer was deposited to a thickness of 1 μm on the buffer layer.

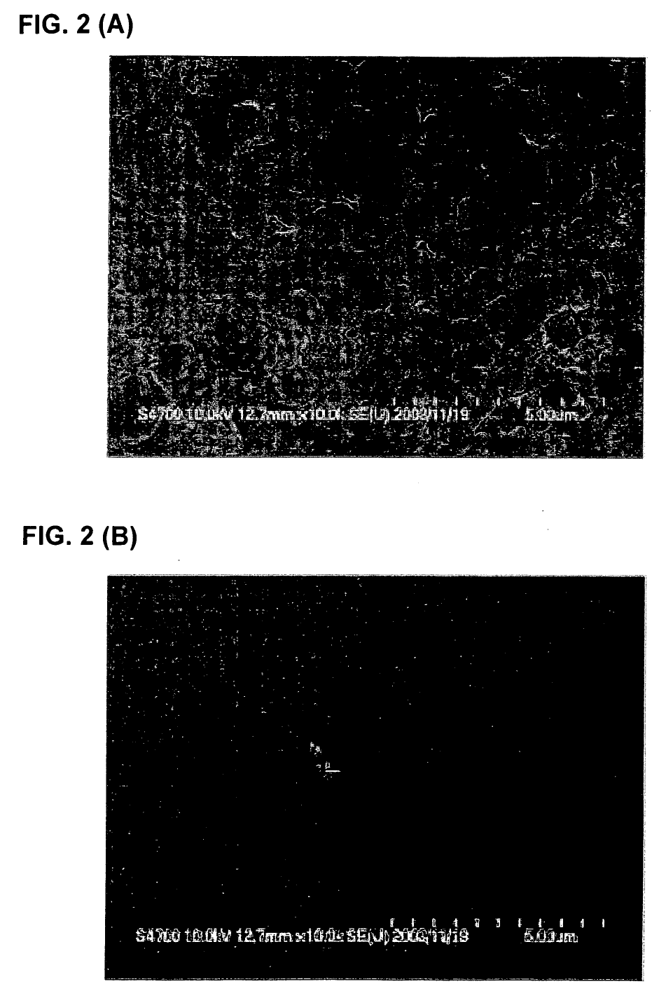

A surface of the potassium niobate layer in the potassium niobate deposited body thus obtained was polished by buff polishing that used a colloidal silica polishing liquid. Scanning electron microscope (SEM) photographs of the surface morphologies of the potassium niobate layer before and after polishing are shown in FIGS. 2(A) and (B). As shown in FIG. 2(A), it was confirmed that the surface of the potassium niobate layer before polishing consisted of polycrystal particles, and was inferior in its surface morphology. In contrast, it was confirmed that the surface of the potassium niobate layer after polishing had a smooth surface, as shown in FIG. 2(B).

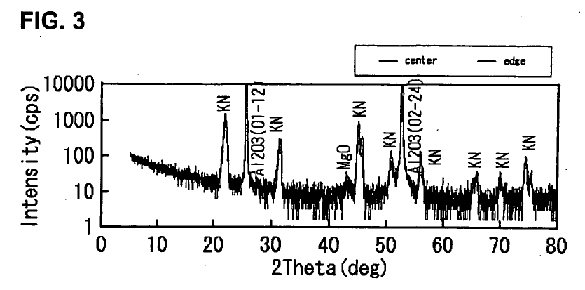

Also, an X-ray diffraction pattern (2θ-θ scanning) of the potassium niobate layer obtained in the present embodiment example is shown in FIG. 3. All peaks shown in the X-ray diffraction pattern of FIG. 3 belong to sapphire and potassium niobate, and peaks belonging to other compounds are not observed. Therefore, it was confirmed that the potassium niobate layer obtained in the present embodiment example was a polycrystal but in a single phase.

### (2) Second Embodiment Example

A potassium niobate deposited body was formed by the following method. In this embodiment example, a single crystal potassium niobate layer could be obtained.

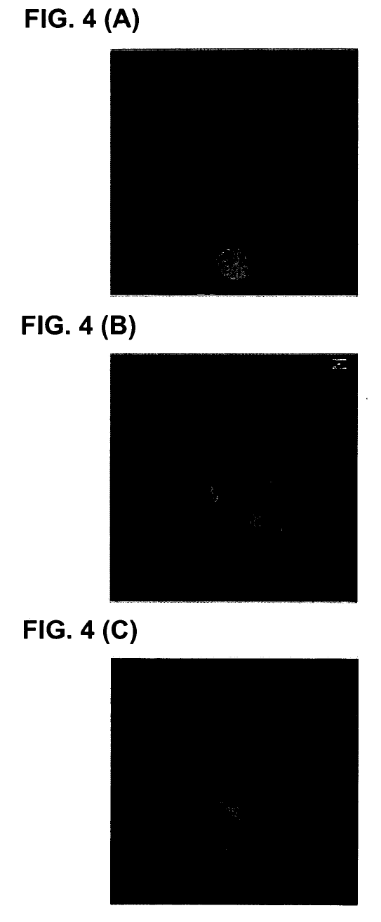

First, a sapphire single crystal substrate was degreased and washed by soaking the sapphire single crystal substrate in an organic solvent with an ultrasonic washing machine. As the organic solvent, a 1:1 mixed solution of ethyl alcohol and acetone was used. After loading the sapphire single crystal substrate that had been degreased and washed onto a substrate holder, it was introduced together with the substrate holder in a vacuum apparatus whose back pressure at room temperature was 1×10⁻⁸ Torr, oxygen gas was introduced such the oxygen partial pressure became 5×10⁻⁵ Torr, and then the substrate was heated to elevate its temperature up to 400° C. at a rate of 20° C./minute with an infrared ray lamp. At this time, as shown in FIG. 4(A), in a pattern obtained by the reflection high speed electron beam diffraction (Reflection High Energy Electron Diffraction (RHEED)) in a sapphire [11-20] direction, kikuchi lines and strong reflection points that are characteristic to a single crystal were observed.

Next, a pulsed beam of KrF excimer laser (with a wavelength of 248 nm) was injected in a surface of a magnesium target under conditions with an energy density being 3 J/cm², a frequency being 20 Hz, and a pulse length being 10 ns, thereby generating a plasma plume of magnesium on the target surface. The plasma plume was irradiated to the sapphire single crystal substrate at a position 70 mm away from the target for 30 minutes under conditions with a substrate temperature being 400° C. and an oxygen partial pressure being 5×10⁻⁵ Torr, whereby a buffer layer consisting of MgO was deposited to a thickness of 10 nm. A RHEED pattern in a sapphire [11-20] direction of the deposited body thus obtained was investigated, and a pattern shown in FIG. 4(B) was obtained. A diffraction pattern appears in this RHEED pattern, and it was confirmed that the buffer layer of MgO epitaxially grew.

Next, a pulsed beam of KrF excimer laser was injected in a surface of a K_{0.67}Nb_{0.33}O_{y} target under conditions with an energy density being 2 J/cm², a frequency being 10 Hz, and a pulse length being 10 ns, thereby generating a plasma plume of K, Nb and O. The plasma plume was irradiated to the sapphire single crystal substrate at a position 70 mm away from the target for 240 minutes under conditions with a substrate temperature being 600° C. and an oxygen partial pressure being 1×10⁻² Torr, whereby a potassium niobate (KNbO₃) layer was deposited to a thickness of 0.5 μm on the buffer layer.

A RHEED pattern in a sapphire [11-20] direction of the deposited body thus obtained was investigated, and a pattern shown in FIG. 4(C) was obtained. A diffraction pattern clearly appears in this pattern, and it was confirmed that potassium niobate epitaxially grew.

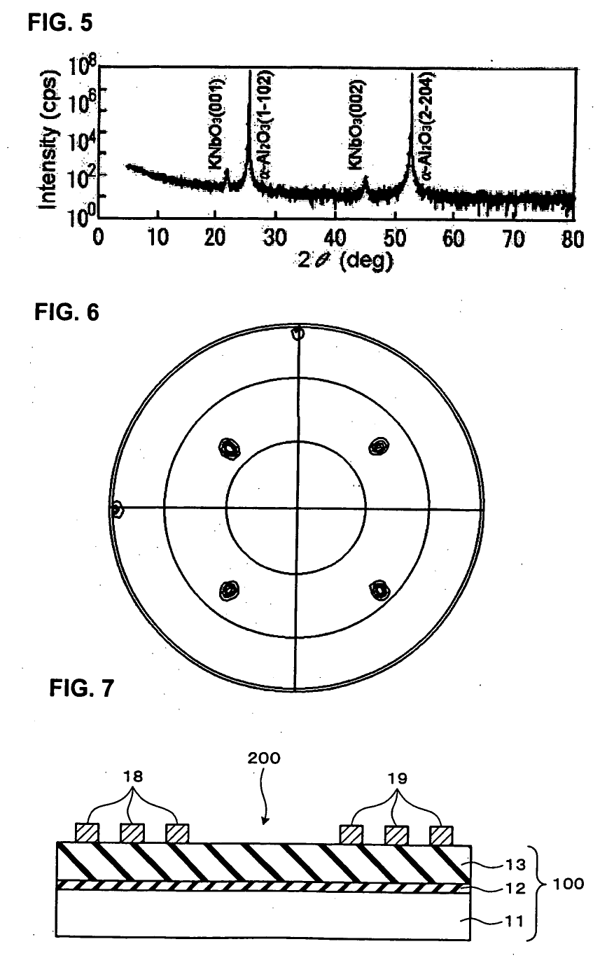

Further, an X-ray diffraction pattern (2θ-θ scanning) of the potassium niobate (KNbO₃) layer obtained in the present embodiment example is shown in FIG. 5. It was confirmed from the X-ray diffraction pattern in FIG. 5 that only KNbO₃ (001) and KNbO₃ (002) peaks were observed besides peaks of the sapphire substrate, and therefore KNbO₃ was (001) oriented (c-axis oriented).

Moreover, when an X-ray diffraction pole figure of a KNbO₃ (111) peak was investigated, the result shown in FIG. 6 was obtained. In FIG. 6, spots indicating symmetry four times are observed at 30 degrees<Psi<60 degrees, and therefore it was found that the KNbO₃ layer had undergone epitaxial growth in an (001) orientation (c-axis orientation), and had two domains whose [010] axes (polarization axes) are different by 90 degrees in the in-plane orientation existed therein. Also, as the center of these four spots is shifted from the center of the pole figure (Psi=0 degree) by 10 degrees, it was confirmed that the KNbO₃ layer had epitaxially grown in a state in which its [001] vector was inclined by about 10 degrees with respect to a normal vector of the sapphire R-plane (1-102).

According to the present embodiment as described above, when a potassium niobate layer is formed by using a vapor phase method, a single phase thin film of potassium niobate can be epitaxially grown in a c-axis orientation, by using a R-plane sapphire single crystal substrate and a buffer layer consisting of MgO with a cubic (100) orientation. With such a potassium niobate thin film, a surface acoustic wave element having a large electromechanical coupling coefficient can be obtained. Therefore, by applying this surface acoustic wave element, further miniaturization of frequency filters and frequency oscillators can be realized, and power saving of electronic circuits and electronic apparatuses becomes possible.

### 2. Surface Acoustic Wave Element

FIG. 7 is a cross-sectional view schematically showing a surface acoustic wave element 200 in accordance with an embodiment of the present invention.

The surface acoustic wave element 200 is formed from a potassium niobate deposited body in accordance with the present invention, for example, a potassium niobate deposited body 100 (see FIG. 1) described above in Section 1. More specifically, a buffer layer 12 and a potassium niobate layer 13 are sequentially deposited on a sapphire single crystal substrate 11. Further, inter-digital transducers (hereafter, referred to as “IDT electrodes”) 18 and 19 having a predetermined pattern are formed on the potassium niobate layer 13.

The potassium niobate layer 13 is formed from a polycrystal or single crystal potassium niobate, as described in Section 1. In the present embodiment, sodium potassium niobate tantalate solid solution (K₁₋ₓ NaₓNb_{1-y} Ta_{y}O₃ (0<x<1, 0<y<1)) can be used instead of potassium niobate (KNbO₃). The same similarly applies to each element described below.

The surface acoustic wave element 200 is formed for example as follows.

First, by a vacuum deposition method using metal such as aluminum, a metal layer is deposited on the potassium niobate layer 13 of the potassium niobate deposited body 100. Next, the metal pattern is patterned by using known lithography and dry etching techniques, to thereby form IDT electrodes 18 and 19 on the potassium niobate layer 13.

An example of experiments conducted on the surface acoustic wave element in accordance with the present embodiment is described below.

(1) A surface acoustic wave element was formed by using the potassium niobate deposited body of the first embodiment example described in Section 1.3 (1). The potassium niobate deposited body had a polycrystal potassium niobate layer of a single phase. It is noted that, as the IDT electrodes, aluminum layers of 100 nm in thickness were used.

In the obtained surface acoustic wave element, an acoustic velocity obtained based on a delay time Vₒₚₑₙ of a surface acoustic wave between the IDT electrode 18 and 19 was 5000 m/s. Also, an electromechanical coupling coefficient obtained based on a difference between the above and a delay time Vₛₕₒᵣₜ of a surface acoustic wave when an area between the IDT electrodes 18 and 19 was covered by a metal thin film was 10%.

Also, a surface acoustic wave element using sodium potassium niobate tantalate solid solution (K₁₋ₓ NaₓNb_{1-y} Ta_{y}O₃ (0<x<1, 0<y<1)) instead of potassium niobate (KNbO₃) gave similar effects.

(2) A surface acoustic wave element was formed by using the potassium niobate deposited body of the second embodiment example described in Section 1.3 (2). The potassium niobate deposited body had a single crystal potassium niobate layer. It is noted that, as the IDT electrodes, aluminum layers of 100 nm in thickness were used.

In the obtained surface acoustic wave element, an acoustic velocity obtained based on a delay time Vₒₚₑₙ of a surface acoustic wave between the IDT electrode 18 and 19 was 5000 m/s. Also, an electromechanical coupling coefficient obtained based on a difference between the above and a delay time Vₛₕₒᵣₜ of a surface acoustic wave when an area between the IDT electrodes 18 and 19 was covered by a metal thin film was 35% because the potassium niobate layer was a single crystal with a (001) orientation. As compared to the electromechanical coupling coefficient (10%) obtained when the polycrystal potassium niobate layer described above in (1) was used, it became clear that the electromechanical coupling coefficient improved by epitaxially growing the potassium niobate layer in a (001) orientation.

### 3. Frequency Filter

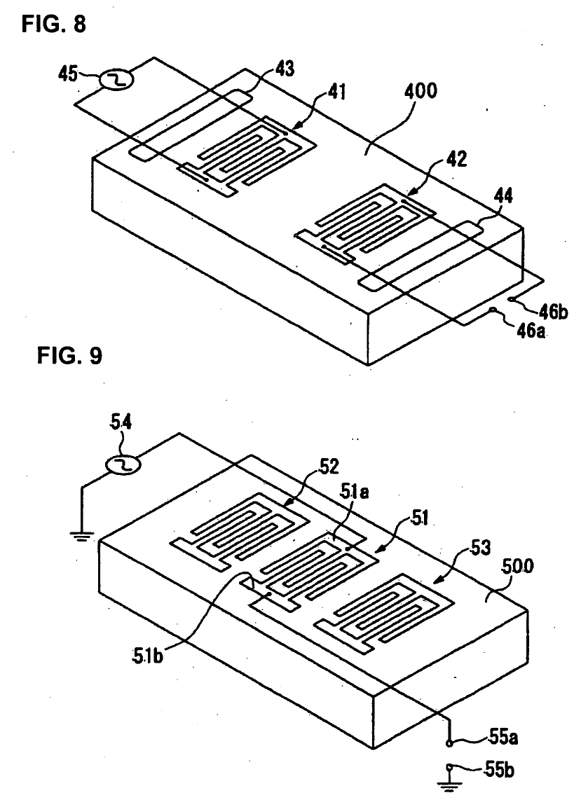

FIG. 8 is a perspective view showing the outer appearance of a frequency filter in accordance with an embodiment of the present invention.

The frequency filter shown in FIG. 8 is formed from a potassium niobate deposited body in accordance with the present invention, for example, a potassium niobate deposited body 100 (hereafter referred to as a “base substrate 400”) described in Section 1. More specifically, the base substrate 400 has a structure in which a buffer layer and a potassium niobate layer are successively deposited on a sapphire single crystal substrate. The frequency filter includes IDT electrodes 41 and 42 having a predetermined pattern formed on the potassium niobate layer of the base substrate 400.

The IDT electrodes 41 and 42 are formed from, for example, aluminum or an aluminum alloy. Also, the thickness of the IDT electrodes 41 and 42 is set to about 1/100 of the pitch of the IDT electrode 41, 42. Moreover, acoustic absorber sections 43 and 44 are formed on the base substrate 400. The acoustic absorber sections 43 and 44 absorb surface acoustic waves that propagate over the surface of the base substrate 400. A high frequency signal source 45 is connected to one of the IDT electrodes 41 formed on the substrate 400, and a signal line is connected to the other of the IDT electrodes 42.

When a high frequency signal is outputted from the high frequency signal source 45 in the above-described design, the high frequency signal is impressed on the IDT electrode 41. As a result, a surface acoustic wave is generated on the upper surface of the base substrate 40. This surface acoustic wave propagates over the top surface of the base substrate 400 at a speed of approximately 4000 m/s. The surface acoustic waves propagating from the IDT electrode 41 toward the sound absorbing portion 43 are absorbed at the sound absorbing portion 43. However, from among the surface acoustic waves propagating toward the IDT electrode 42, only those surface acoustic waves with a specific frequency or specific band frequency determined according to the pitch and the like of the IDT electrode 42 are converted to electric signals, and outputted to terminals 46a and 46b via the signal line. It is noted that that the majority of the frequencies that are not the aforementioned specific frequency or specific band frequency are absorbed by the sound absorbing portion 44 after passing through the IDT electrode 42.

In this way, of the electric signals supplied to the IDT electrode 41 provided in the frequency filter of the present embodiment, it is possible to obtain only surface acoustic waves of a specific frequency or specific band frequency (i.e., filtering is possible).

### 4. Frequency Oscillator

FIG. 9 is a perspective view showing the outer appearance of a frequency oscillator in accordance with an embodiment of the present invention. The frequency oscillator shown in FIG. 9 includes a potassium niobate deposited body in accordance with the present invention, for example, a potassium niobate deposited body 100 described in Section 1 (hereafter referred to as a “base substrate 500”). More specifically, the base substrate 500 has a structure in which a buffer layer and a potassium niobate layer are successively deposited on a sapphire single crystal substrate. The frequency oscillator further includes an IDT electrode 51 having a predetermined pattern formed on the potassium niobate layer of the base substrate 500, and IDT electrodes 52 and 53 are formed so that the IDT electrode 51 is interposed therebetween. The IDT electrodes 51, 52 and 53 are formed from aluminum or an aluminum alloy, for example. The thickness of each of the IDT electrodes 51, 52 and 53 is set to about 1/100 of each of their pitches, respectively. A high frequency signal source 54 is connected to one of the comb teeth-shaped electrodes 51a which form the IDT electrode 51, while a signal line is connected to the other comb teeth-shaped electrode 51b. It is noted that the IDT electrodes 52 and 53 correspond to resonating electrodes for resonating a specific frequency component or a specific band frequency component of the surface acoustic waves generated by the IDT electrode 51.

When a high frequency signal is outputted from the high frequency signal source 54 in the above-described design, this high frequency signal is impressed on one of the comb teeth-shaped electrodes 51a of the IDT electrode 51. As a result, surface acoustic waves that propagate toward the IDT electrode 52 and surface acoustic waves that propagate toward the IDT electrode 53 are generated on the upper surface of the base substrate 500. It is noted that the speed of this surface acoustic wave is approximately 4000 m/s. Of these surface acoustic waves, those surface acoustic waves of a specific frequency component are reflected at the IDT electrode 52 and the IDT electrode 53, and a standing wave is generated between the IDT electrode 52 and the IDT electrode 53. The surface acoustic wave of this specific frequency is repeatedly reflected at the IDT electrode 52 and the IDT electrode 53. As a result, specific frequency components or specific band frequency components are resonated and the amplitude increases. A portion of the surface acoustic waves of the specific frequency component or the specific band frequency component are extracted from the other comb teeth-shaped electrode 51b of the IDT electrode 51, and the electric signal of the frequency (or the frequency having a certain band) corresponding to the resonance frequency between the IDT electrode 52 and the IDT electrode 53 can be extracted at terminals 55a and 55b.

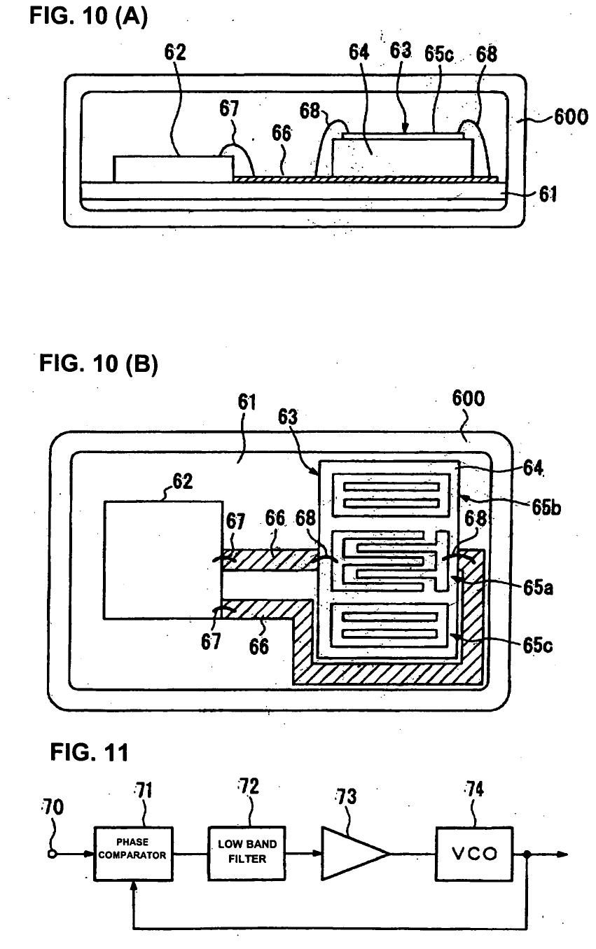

FIGS. 10(A) and (B) are views showing an example in which the surface acoustic wave element in accordance with an embodiment of the present invention is employed as a VCSO (Voltage Controlled SAW Oscillator). FIG. 10(A) is a cut-out side view, and FIG. 10(B) is a cut-out plan view. The VCSO is housed inside a metallic (aluminum or stainless) box 600. The numeral 61 denotes a substrate. An IC (integrated circuit) 62 and a frequency oscillator 63 in accordance with the present invention are mounted on the substrate 61. The IC 62 controls the frequency to be impressed on the frequency oscillator 63 in response to the voltage inputted from an external circuit (not shown).

The frequency oscillator includes a potassium niobate deposited body in accordance with the present invention, for example, a potassium niobate deposited body 100 described in Section 1 (hereafter referred to as a “base substrate 64”). More specifically, the base substrate 64 has a structure in which a buffer layer and a potassium niobate layer are successively deposited on a sapphire single crystal substrate. The frequency oscillator 63 further includes IDT electrodes 65a, 65b and 65c each having a predetermined pattern formed on the potassium niobate layer of the base substrate 64, and their structures are generally the same as those of the frequency oscillator shown in FIG. 9.

A wiring 66 for electrically connecting the IC 62 and the frequency oscillator 63 is patterned on the substrate 61. For example, the IC 62 and the wiring 66 are connected by a wire line 67 such as a gold line, and the frequency oscillator 63 and the wiring 66 are connected by a wire line 68 such as a gold line, whereby the IC 62 and frequency oscillator 63 are electrically connected through the wiring 66.

The VCSO shown in FIGS. 10(A) and (B) can be employed as a VCO (Voltage Controlled Oscillator) for a PLL circuit shown in FIG. 11, for example. The PLL circuit is now briefly explained. FIG. 11 is a block diagram showing the basic structure of a PLL circuit. As shown in FIG. 11, the PLL circuit consists of a phase comparator 71, a low band filter 72, an amplifier 73 and a VCO 74.

The phase comparator 71 compares the phases (or frequencies) of signals inputted from an input terminal 70 and outputted from the VCO 74, and outputs an error voltage signal, the value of which is set according to the difference between these signals. The low band filter 72 transmits only the low frequency components at the position of the error voltage signal outputted from the phase comparator 71, and the amplifier 73 amplifies the signal outputted from the low band filter 72. The VCO 74 is an oscillator circuit in which the oscillation frequency is continuously changed within a region, corresponding to the voltage value inputted. The PLL circuit operates so as to decrease the difference between the phases (or frequencies) inputted from the input terminal 70 and outputted from the VCO 74, and synchronizes the frequency of the signal outputted from the VCO 74 with the frequency of the signal inputted from the input terminal 70. When they are synchronized, the PLL circuit outputs a signal that matches with the signal inputted from the input terminal 70 after excluding a specific phase difference, and conforms to the changes in the input signal.

### 5. Electronic Circuit

### 5.1 First Example

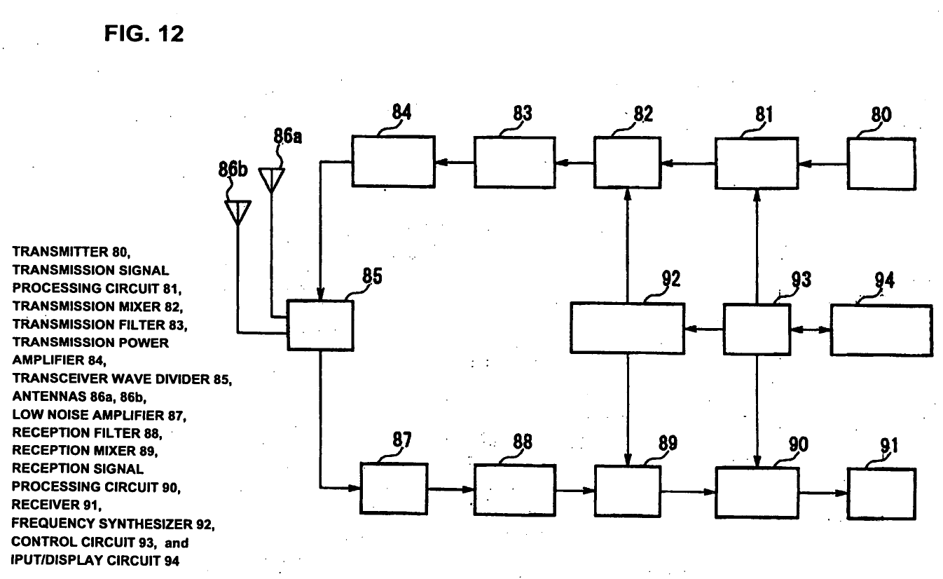

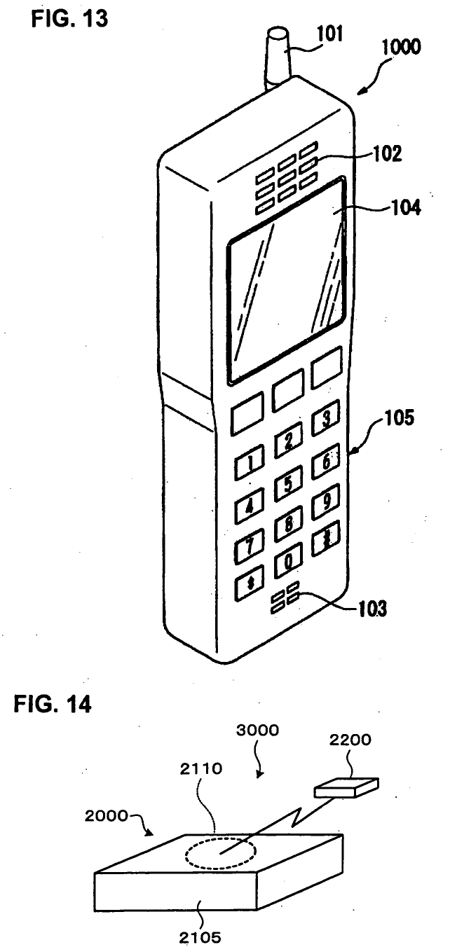

FIG. 12 is a block diagram showing an electrical structure of an electronic circuit in accordance with an embodiment of the present invention. It is noted that the electronic circuit in FIG. 12 is a circuit that is provided inside a cellular phone 1000 shown in FIG. 13, for example. FIG. 13 is a perspective view showing an example of the external appearance of the cellular phone which is shown here as an example of an electronic apparatus in accordance with an embodiment of the present invention. The cellular phone 1000 shown in FIG. 13 consists of an antenna 101, a receiver 102, a transmitter 103, a liquid crystal display 104, operating buttons 105, and the like.

The electronic circuit shown in FIG. 12 shows the basic structure of an electronic circuit provided inside the cellular phone 1000, and is equipped with a transmitter 80, a transmission signal processing circuit 81, a transmission mixer 82, a transmission filter 83, a transmission power amplifier 84, a transceiver wave divider 85, antennas 86a, 86b, a low noise amplifier 87, a reception filter 88, a reception mixer 89, a reception signal processing circuit 90, a receiver 91, a frequency synthesizer 92, a control circuit 93, and an input/display circuit 94. It is noted that the cellular phones currently in use have a more complicated circuit structure due to the fact that they perform frequency converting processes multiple times.

The transmitter 80 can be realized with a microphone which converts sound wave signals into electric signals, for example, and may correspond to the transmitter 103 shown in FIG. 13. The transmission signal processing circuit 81 is a circuit for performing such processing as D/A conversion, modulation, etc. on the electric signal to be outputted from the transmitter 80. The transmission mixer 82 mixes the signal outputted from the transmission signal processing circuit 81 using the signal outputted from the frequency synthesizer 92. It is noted that the frequency of the signal supplied to the transmission mixer 82 is 380 MHz, for example. The transmission filter 83 permits passage of only those signals of the required frequency from among the intermediate frequencies (hereafter referred to as “IF”), and cuts unnecessary frequency signals. It is noted that the signal outputted from the transmission filter 83 is converted to an RF signal by a converting circuit (not shown). The frequency of this RF signal is about 1.9 GHz, for example. The transmission power amplifier 84 amplifies the power of the RF signal outputted from the transmission filter 83 and outputs this amplified result to the transceiver wave divider 85.

The transceiver wave divider 85 transmits the RF signal that is outputted from the transmission power amplifier 84 through the antennas 86a and 86b in the form of radio waves. Also, the transceiver wave divider 85 divides the reception signal received by the antennas 86a and 86b, and outputs the result to the low noise amplifier 87. It is noted that the frequency of the reception signal outputted from the transceiver wave divider 85 is, for example, about 2.1 GHz. The low noise amplifier 87 amplifies the reception signal from the transceiver wave divider 85. It is noted that the signal outputted from the low noise amplifier 87 is converted to an intermediate signal (IF) by a converting circuit (not shown).

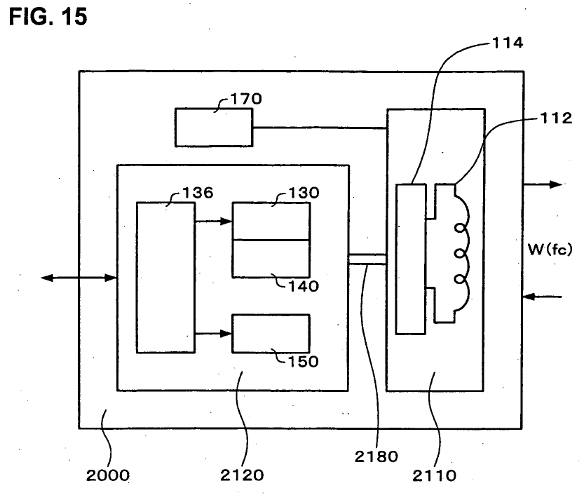

The reception filter 88 permits passage of only those signals of the required frequency from among the intermediate frequencies (IF) that were converted by a converting circuit (not shown), and cuts unnecessary frequency signals. The reception mixer 89 employs the signal outputted from the frequency synthesizer 92 to mix the signals outputted from the transmission signal processing circuit 81. It is noted that the intermediate frequency supplied to the reception mixer 89 is, for example, about 190 MHz. The reception signal processing circuit 90 performs such processing as A/D conversion, modulation, etc., to the signal outputted from the reception mixer 89. The receiver 91 is realized by means of a small speaker which converts electric signals into sound waves, for example, and corresponds to the receiver 102 shown in FIG. 15.

The frequency synthesizer 92 is a circuit for generating the signal (at a frequency of 380 MHz, for example) to be supplied to the transmission mixer 82 and the signal (at a frequency of 190 MHz, for example) to be supplied to the reception mixer 89. The frequency synthesizer 92 is equipped with a PLL circuit for generating a signal oscillating at 760 MHz, for example. The frequency synthesizer 92 divides the signal outputted from this PLL circuit and generates a 380 MHz frequency signal, for example, and then further divides this signal to generate a 190 MHz signal. The control circuit 93 controls the transmission signal processing circuit 81, the reception signal processing circuit 90, the frequency synthesizer 92, and the input/display circuit 94, thereby controlling the overall operation of the cellular phone. The input/display circuit 94 displays the device status to the user of the cellular phone 1000, and is provided for the user to input directions. This input/display circuit 94 corresponds, for example, to the liquid crystal display 104 and the operating buttons 105 shown in FIG. 13.

In an electronic circuit of the above-described structure, the frequency filter shown in FIG. 8 is employed as the transmission filter 83 and the reception filter 88. The frequency that is filtered (i.e., the frequency which is permitted to pass through the filter) is set separately at the transmission filter 83 and the reception filter 88 in response to the required frequency in the signal outputted from the transmission mixer 82 and the required frequency at the reception mixer 89. The PLL circuit that is provided within the frequency synthesizer 92 is provided with the frequency oscillator shown in FIG. 9 or the frequency oscillator (VCSO) shown in FIGS. 10(A) and (B) as the VCO 74 of the PLL circuit shown in FIG. 13.

### 5.2 Second Example

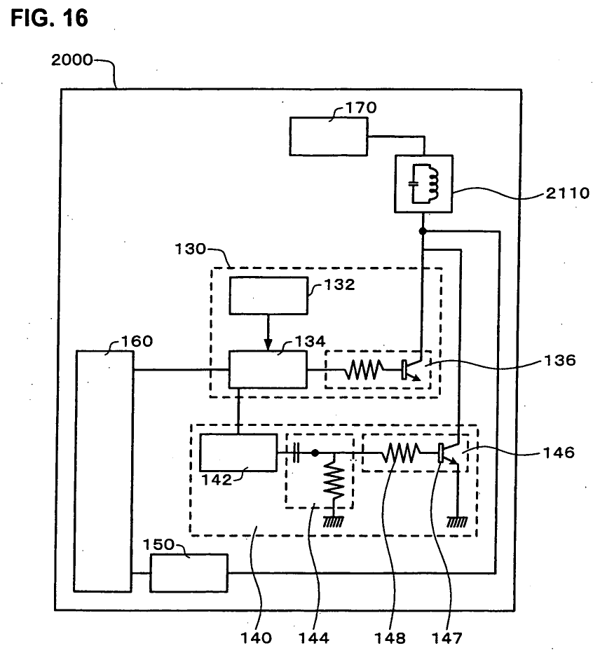

FIG. 16 is a block diagram showing the electrical structure of an electronic circuit in accordance with an embodiment of the present invention. It is noted that the block diagram shown in FIG. 16 may be a circuit diagram of a circuit that is provided in, for example, a reader/write 2000 shown in FIG. 14 and FIG. 15.

A reader/writer 2000 in accordance with an embodiment of the present invention and a communications system 3000 using the same are described with reference to FIGS. 14-16. The communications system 3000 includes the reader/writer 2000 and a contactless information medium 2200, as shown in FIG. 14. FIG. 15 is a block diagram schematically showing the reader/writer in FIG. 14. FIG. 16 is a circuit diagram schematically showing the structure of the reader/writer 2000 shown in FIG. 15.

The reader/writer 2000 transmits a radio wave W (which may also be hereafter referred to as a “career”) having a carrier frequency f_{c} to the contactless information medium 2200 or receives the same from the contactless information medium 2200, to thereby communicate with the contactless information medium 2200 by using radio communications. The radio wave W can use any carrier frequency fc in an arbitrary frequency band (for example, 13.56 MHz). As shown in FIG. 14 and FIG. 15, the reader/writer 2000 has a main body 2105, an antenna section 2110 located on the top surface of the main body 2105, a control interface section 2120 stored in the main body 2105, and a power supply circuit 170. The antenna 2110 and the control interface section 2120 are electrically connected with a cable 2180. Further, the reader/writer 2000 is connected to an external host device (processor, controller device, personal computer, display, etc.) (not shown) through the control interface section 2120.

The antenna section 2110 has a function to communicate information with the contactless information medium 2200. The antenna section 2110 is located on the upper surface of the communication device 2000, and has a prescribed communication area (area shown by a dotted line in the figure), as shown in FIG. 14. The antenna section 2110 is composed of a loop antenna 112 and a matching circuit 114.

A transmission section 130, a damping oscillation cancellation section (hereafter, referred to as a “cancellation section”) 140, a reception section 150, and a controller 160 are built into the control interface section 2120.

The transmission section 130 modulates data transmitted from an external unit (not shown), and transmits the same to the loop antenna 112.

The transmission section 130 has an oscillation circuit 132, a modulation circuit 134, and a driving circuit 136. The oscillation circuit 132 is a circuit for generating a carrier of a prescribed frequency, and is usually composed by the use of a quartz oscillator or a ceramic oscillator. Further, by using a frequency oscillator in accordance with the present invention in the oscillation circuit 132, its communication frequency can be improved to a higher frequency and its detection sensitivity can be improved.

The modulation circuit 134 is a circuit that modulates the carrier according to information given, and can be composed of, for example, ordinary CMOS AND gate circuits. In this case, as the modulation method, an ASK (Amplitude Shift Keying) 100% method that is a kind of an amplitude modulation method may be used. However, other modulation methods, such as, for example, a PSK (Phase Shift Keying) method, a FSK (Frequency Shift Keying) method, or the like can be used. Finally, the driving circuit 136 receives the modulated career, amplifies its electric power, and drives the antenna section 2110. The driving circuit 136 is composed of a resistance and a transistor in the present embodiment. The transmission section 130 described in the present specification is illustrative, and does not exclude applications of an equivalent composition of the same.

The cancellation section 140 has a function to control a damped oscillation generated by the loop antenna 112 of the antenna section 2110 which occurs with ON/OFF of the career. The cancellation section 140 has a logic circuit 142 and a cancellation circuit 146. A transistor 147 to be described below of the cancellation circuit 146 and the transistor of the driving circuit 136 are connected to form a wired OR.

The reception section 150 has a detection device (current detection device) (not shown) and a demodulator circuit, and demodulates a signal that is transmitted from the contactless information medium 2200. In the present embodiment, the detection device is a device that detects changes in the current that circulates in the loop antenna 112, and, for example, can be composed of a well-known current detection device. It is noted that, though the detection device is realized as a current detection device in the present embodiment, it can have any structure that is capable of detecting signals transmitted from the contactless informational medium 2200. Moreover, the demodulation circuit is a circuit that demodulates a change detected by the current detection device, but does not exclude applications of any known technology.

The controller 160 retrieves information from the demodulated signal, and transfers the same to an external device. The controller 160 may be composed of, for example, a CPU, and may be a different control and/or processing circuit.

The power supply circuit 170 receives the supply of an electric power from outside, appropriately converts the voltage, and supplies a necessary electric power to each circuit, but may use a built-in battery as the power source depending on circumstances. The power supply circuit 170 drives the antenna 2110 with a power supply of 15V in the present embodiment. Any well-known technology is applicable to the power supply circuit 170, and its detailed description here is omitted.

Referring again to FIG. 14, the contactless information medium 2200 that is communicatable with the above-described reader/writer 2000 is described.

The contactless information medium 2200 communicates with the reader/writer 2000 by using electromagnetic waves (radio waves). In accordance with present embodiment, the contactless information medium 2200 can have any arbitrary configuration (for example, a pendant shape, coin shape, key shape, card shape, tag shape or the like) that matches with its use, and is realized as a contactless IC tag (which is interchangeably referred to as a contactless IC tag 2200). However, the contactless information medium 2200 may be realized as an IC card having a so-called ISO (International Organization for Standardization) size (54 mm in length, 85.6 mm in width, and 0.76 mm in thickness) IC card that is in the same size as a credit card. Such IC cards do not exclude applications of the medium to card media that has magnetic stripes such as credit cards and cash cards. Furthermore, the contactless information medium 2200 may be selectively provided with an embossment, a signature panel, a hologram, a stamp, a hot stamp, an image print, a photograph, etc.

Next, operations of the communication system 3000 that uses the reader/writer 2000 in accordance with the present embodiment are described. When data is sent to the contactless IC tag 2200 from the reader/writer 2000, if the data is sent from an external device (not shown), the data is processed by the controller 160 in the reader/writer 2000 and sent to the transmission section 130. In the transmission section 130, a high frequency signal of a constant amplitude is supplied from the oscillation circuit 132 as a career, the career is modulated by the data and a modulated high frequency signal is outputted. In this case, the modulation method can be an amplitude modulation method, a frequency modulation method, a phase modulation method, or the like. The modulated high frequency signal outputted from the modulation circuit 134 is supplied to the antenna 2110 through the driving circuit 136.

In the present embodiment, at the same time, the damping oscillation cancellation section 140 generates a predetermined pulse signal in synchronism with an OFF timing of the modulated high frequency signal, to thereby contribute to the control of the damping oscillation in the loop antenna 112. As a result, the reader/writer 2000 can obtain excellent communications with the contactless information medium 2200.

At this time, as the contactless IC tag 2200 is adjacent to the reader/writer 2000, the loop antenna 112 of the reader/writer 2000 and a coil (not shown) of the contactless IC tag 2200 are electromagnetically coupled with one another.

Then, in the contactless IC tag 2200, the modulated high frequency signal is supplied to a reception circuit (not shown). Also, the modulated high frequency signal is supplied to a power supply circuit (not shown), and a predetermined power supply voltage (for instance, 3.3 V) necessary for each section of the contactless IC tag 2200 is generated. Moreover, the data outputted from the reception circuit (not shown) is demodulated and supplied to a logic control circuit (not shown). The logic control circuit (not shown) operates based on the output of a clock (not shown), processes the supplied data, and writes certain data in a memory (not shown).

When data is sent from the contactless IC tag 2200 to the reader/writer 2000, the following operations take place. In the reader/writer 2000, a high frequency signal of a constant amplitude is outputted from the modulation circuit 134 without being modulated, and sent to the contactless IC tag 2200 through the driving circuit 136 and the loop antenna 112 of the antenna section 2110.

On the other hand, in the contactless IC tag 2200, data read from the memory (not shown) is processed by the logic control circuit (not shown), and supplied to a transmission and reception circuit (not shown). A transmission circuit (not shown) of the transmission and reception circuit (not shown) can be composed of, for example, a load resistance and a switch, wherein the switch turns ON and OFF according to “1” and “0” bit of the data.

In the reader/writer 2000, when the switch of the transmission circuit (not shown) of the transmission and reception circuit turns ON and OFF, the load, as viewed to the side of the loop antenna 112 from the both terminals of the loop antenna 112 of the antenna section 2110, fluctuates, and therefore, the amplitude of the high frequency current that circulates in the loop antenna 112 fluctuates. In other words, the high frequency current is amplitude-modulated by the data supplied from the logic control circuit (not shown) of the contactless IC tag 2200 to the transmission circuit (not shown). The high frequency current is detected by the current detection device (not shown) of the reception section 150, and demodulated by the reception circuit (not shown) whereby data is obtained. The data is processed by the controller 160, and transmitted to an external apparatus (not shown).

The communications system 3000 described above is expected to be used for multiple purposes in various fields as well as contactless IC cards and IC tags. These fields include finance (cash cards, credit cards, electronic money management, firm banking, home banking, etc.), circulation (shopping cards, gift certificates, etc.), medical treatment (consultation cards, health insurance certificates, health pocketbooks, etc.), traffic (stored fair (SF) cards, coupon tickets, license certificates, commutation tickets, passports, etc.), insurance (insurance policy, etc.), bond (bonds, etc.), education (student's identification cards, transcripts, etc.), enterprise (identification cards, etc.), administration (stamp certificates, resident cards, etc.), and the like. For example, when the contactless IC tag 2200 stores ID information in its memory, the communication system 3000 can be used as an input/output control medium for corporations, laboratories, universities and the like.

Although the surface acoustic wave element, frequency filter, frequency oscillator, electronic circuit, electronic equipment, and reader/writer in accordance with the embodiments of the present invention are described above, the present invention can be freely modified within the scope of the present invention without being limited to the embodiments described above. For example, in the embodiments described above, the cellular phone is described as an example of an electronic apparatus, and the electronic circuit installed in the cellular phone is described as an example of an electronic circuit. However, the present invention is not limited to the cellular phone, but can be applied to various mobile telecommunications equipment and electronic circuits installed therein.

Moreover, the present invention can be applied not only to mobile telecommunications equipment, but also to floor type telecommunications equipment such as tuners that receive BS (Broadcast Satellite) and CS (Commercial Satellite) broadcasting, and electronic circuits installed therein. Furthermore, the present invention is applicable not only to telecommunications equipment that use electric waves that propagate through air as communication careers, but also to electronic equipment such as HUB or the like that use high frequency signals that propagate in coaxial cables, optical signals that propagate in optical cables and the like, and electronic circuits installed therein.

In addition, the present invention is also applicable to wide-band filters in UWB (Ultra Wide Band) systems, wide-band filters of cellular phones, VCSOs and wide-band filters of wireless LAN, and the like.

According to the potassium niobate deposited body in accordance with the present invention described above, surface acoustic wave elements having a large electromechanical coupling coefficient can be realized, miniaturization of frequency filters and frequency oscillators can be achieved, and power saving of electronic circuits and electronic apparatuses can be realized.

1. A potassium niobate deposited body comprising:
a sapphire substrate; and
a potassium niobate layer formed above the sapphire substrate.

2. A potassium niobate deposited body according to claim 1, further comprising a buffer layer consisting of a metal oxide formed above the sapphire substrate, wherein the potassium niobate layer is formed above the buffer layer.

3. A potassium niobate deposited body according to claim 1, wherein the potassium niobate layer includes a domain having a polarization axis that is in parallel with the sapphire substrate.

4. A potassium niobate deposited body according to claim 1, wherein the potassium niobate layer includes a domain that epitaxially grows in a (001) orientation, when a lattice constant of orthorhombic potassium niobate is 2^{1/2} c<a<b, and a b-axis is a polarization axis.

5. A potassium niobate deposited body according to claim 1, wherein the sapphire substrate is an R-plane (1-102).

6. A potassium niobate deposited body according to claim 2, wherein the buffer layer consists of a metal oxide having a rock salt structure.

7. A potassium niobate deposited body according to claim 6, wherein the metal oxide is magnesium oxide.

8. A potassium niobate deposited body according to claim 7, wherein the magnesium oxide is epitaxially grown in a cubic (100) orientation.

9. A potassium niobate deposited body according to claim 8, wherein a [100] direction vector of the magnesium oxide and a [001] direction vector of the epitaxially grown domain of the potassium niobate layer are inclined with respect to a normal vector of the R-plane (1-102) of the sapphire substrate.

10. A potassium niobate deposited body according to claim 9, wherein the [100] direction vector of the magnesium oxide and the [001] direction vector of the epitaxially grown domain of the potassium niobate layer are inclined at 1 degree or greater but 20 degrees or less with respect to a normal vector of the R-plane (1-102) of the sapphire substrate.

11. A potassium niobate deposited body comprising:
a sapphire substrate; and
a layer of potassium niobate solid solution formed above the sapphire substrate.

12. A potassium niobate deposited body according to claim 11, wherein
the layer of potassium niobate solid solution consists of a solid solution shown by K₁₋ₓ NaₓNb_{1-y} Ta_{y}O₃ (0<x<1, 0<y<1).

13. A method for manufacturing a potassium niobate deposited body, comprising:
a step of forming a buffer layer consisting of a metal oxide having a rock salt structure above a sapphire substrate; and
a step of forming a potassium niobate polycrystal or single crystal layer above the buffer layer.

14. A method for manufacturing a potassium niobate deposited body according to claim 13, wherein the metal oxide is magnesium oxide.

15. A method for manufacturing a potassium niobate deposited body according to claim 13, further comprising the step of polishing a surface of the potassium niobate layer.

16. A surface acoustic wave element comprising the potassium niobate deposited body recited in claim 1, and an electrode.

17. A surface acoustic wave element according to claim 16, wherein a surface of the potassium niobate layer or the potassium niobate solid solution layer of the potassium niobate deposited body is polished.

18. A frequency filter comprising the surface acoustic wave element recited in claim 16.

19. A frequency oscillator comprising the surface acoustic wave element recited in claim 16.

20. An electronic circuit comprising the frequency oscillator recited in claim 19.
